(19) United States
(12) Patent Application Publication
(10) Pub. No.: US 2010/0219494 A1
(43) Pub. Date: Sep. 2, 2010

(54) Sub-mm Wireless Ionizing Radiation Detector

(76) Inventor: Hugh J. Barnaby, Tempe, AZ (US)

Correspondence Address: FULBRIGHT & JAWORSKI L.L.P., 600 CONGRESS AVE., SUITE 2400, AUSTIN, TX, 78701, US

(21) Appl. No.: 12/716,163

(22) Filed: Mar. 2, 2010

Related U.S. Application Data
(60) Provisional application No. 61/156,618, filed on Mar. 2, 2009.

(51) Int. Cl. H01L 31/115; H01L 31/18

(52) U.S. Cl. 257/429; 438/56; 257/E31.086

(57) ABSTRACT

One embodiment of a radiation sensing capacitor is presented. The radiation sensing capacitor may include a silicon layer and an insulator layer coupled to the silicon layer. The radiation sensing capacitor may also include a silicon-insulator interface region coupling the silicon layer to the insulator layer and a plurality of hole-trapping precursors formed in the insulator layer proximate to the silicon-insulator interface region.

### CROSS-REFERENCE TO RELATED APPLICATIONS

This application claims priority to co-pending U.S. Provisional Application No. 61/156,618 filed Mar. 2, 2009, the entire contents of which is specifically incorporated herein by reference without disclaimer.

### BACKGROUND OF THE INVENTION

1. Field of the Invention

This invention relates to radiation sensing and more particularly relates to a sub-mm wireless ionizing radiation detector.

2. Description of the Related Art

While there exist many types of solid state micro-scaled radiation detectors (or micro-dosimeters), among the most common are p-intrinsic-n (PIN) dosimeters and radiation sensing field effect transistors (RADFETs). The PIN device is a reverse-biased diode consisting of a large intrinsic silicon region sandwiched between p-type (Group III doped) and n-type (Group V doped) silicon layers [1]. Charges generated in the intrinsic layer by incident ionizing radiation are collected at the diode terminals resulting in an increase in the saturation current, thereby enabling real-time readout of the radiation fluence level [1]. While the PIN diode has the advantage of being a highly accurate device, it has two primary limitations. The first limitation is that ideal operation of the PIN device requires a static reverse bias. Therefore it will dissipate power during exposure. The second limitation is that, as a transient current mode dosimeter, the PIN dosimeter measures dose rate than cumulative dose over time, therefore it is typically less sensitive. Greater radiation sensitivity is achieved by integrating ionizing radiation dose over time. In principle the radiation-induced currents (dose rate levels) in the PIN device may be integrated and stored in solid state memory elements. However, these added memory elements can significantly increase device complexity, cost, and potentially power during the write stage.

The RADFET is by design an intrinsic non-volatile cumulative dose detector and is thus is a more able to meet the listed requirements than the PIN diode. The RADFET, shown in FIG. 1 is structurally similar to a conventional MOSFET. It is fabricated in a standard CMOS flow with a radiation sensitive thermally grown or deposited oxide layer (typically SiO₂) between a crystalline silicon substrate and a degenerately doped polysilicon gate [2]. Ionizing total dose is measured by sampling radiation-induced threshold voltage shifts that occur as a result of positive trapped charge buildup (ΔNₒₜ) in the gate oxide. The impact of radiation dose on the RADFET's drain current (I_{d}) vs. gate voltage (V_{g}) characteristics are shown in FIG. 2a. As the figure indicates, the threshold voltage shifts negatively in response to ionizing radiation exposure. Discounting the effects of interface states, which in practice must be well controlled, i.e., kept at low densities (<3×10¹⁰ cm⁻²), ΔNₒₜ can be related to the shift in threshold voltage as follows:

$$Δ {N}_{ot} = - \frac{{ɛ}_{ox}}{q {t}_{ox}} Δ {V}_{T} , \qquad ( 1 )$$

where ∈ₒₓ is the oxide permittivity, tₒₓ is the oxide thickness (typically greater than 100 nm), and q is the magnitude of electronic charge. Ionizing total dose (D) can therefore be determined via the following equation:

$$D = α Δ {N}_{ot} = - α \frac{{ɛ}_{ox}}{q {t}_{ox}} Δ {V}_{T} , \qquad ( 2 )$$

where α is a electric field and process dependent damage factor constant (typically determined experimentally.

The physical processes that lead from the initial deposition of energy by ionizing radiation in the sensitive gate oxide to the creation of positively charged defects are: 1) the generation of electron-hole pairs, 2) the prompt recombination of a fraction of the generated ehps, 3) the transport of free carriers remaining in the oxide, and 4) the formation of trapped charge via hole trapping in defect precursor sites. These processes are summarized graphically in FIG. 3 [3].

Under appropriate process conditions (which will be discussed in the following section), the RADFET may be fabricated such that even without external biasing there exists a positive electric field in the sensitive oxide directed from the gate towards the silicon substrate. In the presence of this field, electrons surviving initial recombination will rapidly drift (within picoseconds) towards the gate and holes will drift towards the Si/SiO₂ interface by hopping through localized states in the oxide [4]. It should be noted that the fraction of un-recombined carriers, denoted by f_{y}, is a strong function of the oxide field. This field may shift with radiation exposure thereby leading to some non-linear effects, particularly in un-biased RADFETs, which must be accounted for to ensure accurate total dose measurements. The fraction of free, transporting holes in the oxide that get trapped in pre-cursor defects is a function of the density of these oxide defects (Nₜ), the hole capture cross-section (σ), as well as the sensitive oxide thickness. Thus, the damage factor constant (α in Eq. 2) can be analytically expressed as

$$α = \frac{1}{{f}_{y} {N}_{t} σ {g}_{0} {t}_{ox}} , \qquad ( 3 )$$

where g₀ is the conversion constant relating electron-hole pairs generated to dose (8.1×10¹² ehps/cm³ rad). Small changes in deposited dose may therefore be resolved by the RADFET if a may be configured to be small. This may be achieved by fabricating the device to have a high concentration of efficient trapping pre-cursors near the Si/SiO₂ interface and a relatively thick (tₒₓ<50 nm) and sensitive oxide region.

The RADFET's comparative advantage arises from the fact that the dose response is a function of radiation-induced charges that are trapped in the sensitive oxide layer. As such, the RADFET requires no static or dynamic biasing to write information. Dose data is simply stored in charges “stuck” between a control terminal (the gate) and the underlying silicon substrate. The primary limitation of the RADFET with respect to the listed requirements is that it requires a significant amount of power to “read” the information off the device. The threshold voltage, approximated by −V_{gs}, is sampled when a drain-source current (I_{ds}), typically 10 μA, is forced through the source terminal (FIG. 2b). This readout configuration dissipates approximately 10 μW of power. Since on-chip power is often not feasible, the source of power would have to come from magnetic field coupling; a standard approach implemented in many RFID products [5]. In their 2008 paper, Beyer et al. successfully demonstrated the use of RF energy harvesting to power a MOSFET dosimeter and a bidirectional communication interface [5]. There device, however, has several limitations, including its relatively large size (approximately 21 mm×2 mm).

### SUMMARY OF THE INVENTION

One embodiment of a radiation sensing capacitor is presented. The radiation sensing capacitor may include a silicon layer and an insulator layer coupled to the silicon layer. The radiation sensing capacitor may also include a silicon-insulator interface region coupling the silicon layer to the insulator layer and a plurality of hole-trapping precursors formed in the insulator layer proximate to the silicon-insulator interface region.

In one embodiment, the plurality of hole-trapping precursors include oxygen vacancies. In another embodiment, the plurality of hole-trapping precursors may include nano-cluster trapping sites. The insulator layer may include silicon dioxide SiO₂. Also, the silicon layer comprises p-type doped silicon.

In a further embodiment, the radiation sensing capacitor may include a first conductor coupled to the silicon layer, and a second conductor coupled to the insulator layer. The first conductor and the second conductor may be composed of aluminum (Al).

A radiation sensor is also presented. In one embodiment, the radiation sensor includes a radiation sensing capacitor and an antenna coupled to the radiation sensing capacitor. The radiation sensing capacitor may include a silicon layer and an insulator layer coupled to the silicon layer. The radiation sensing capacitor may also include a silicon-insulator interface region coupling the silicon layer to the insulator layer and a plurality of hole-trapping precursors formed in the insulator layer proximate to the silicon-insulator interface region.

In a further embodiment, the radiation sensor may also include an isolation block, wherein the antenna is formed around the isolation block. In particular, the antenna may be a patch antenna. In such an embodiment, the antenna may be made of, e.g., aluminum (Al). The antenna may include a first contact portion and a second contact portion, wherein the first contact portion is coupled to the silicon layer and the second contact portion is coupled to the insulator layer.

In a further embodiment, the radiation sensor may include a plurality of radiation sensing capacitors arranged such that each of the plurality of radiation sensing capacitors are selectably coupled to the antenna. For example, each radiation sensing capacitor may be coupled to a shorting pin formed through the insulator layer.

In one embodiment, the radiation sensor is configured to reflect a response signal having a primary frequency and a plurality of harmonic frequencies in response to interrogation from a remote radio-frequency source. The primary frequency and the harmonic frequencies may be determined by a level of radiation sensed by the radiation sensing capacitor.

A method of manufacturing a radiation sensor is also presented. In one embodiment, the method includes forming a silicon layer, forming an insulator layer coupled to the silicon layer such that a silicon-insulator interface region couples the silicon layer to the insulator layer, and forming a plurality of hole-trapping precursors formed in the insulator layer proximate to the silicon-insulator interface region.

In one embodiment, forming a silicon layer may include providing a silicon substrate having a sacrificial layer formed thereon, etching the sacrificial layer to provide a one or more groove windows, etching one or more grooves into the substrate through the grove windows of the sacrificial layer, removing the sacrificial layer, forming a layer on a first surface of the silicon substrate and in the one ore more grooves, and reducing the thickness of the silicon substrate from a second surface opposite the first surface until at least a portion of the oxide layer formed in the one or more grooves is exposed through the second surface.

The method may also include forming a polysilicon layer on the oxide layer, and forming a metal layer over the polysilicon layer. In a particular embodiment, forming the insulator layer may include forming the insulator layer on the second surface.

Additionally, the method may include forming a patterned poly-silicon layer in the insulator layer, and forming a metal contact with the poly-silicon layer through the insulator layer. The method may also include coupling the silicon layer and the insulator layer to an antenna.

The term “coupled” is defined as connected, although not necessarily directly, and not necessarily mechanically.

The terms “a” and “an” are defined as one or more unless this disclosure explicitly requires otherwise.

The term “substantially” and its variations are defined as being largely but not necessarily wholly what is specified as understood by one of ordinary skill in the art, and in one non-limiting embodiment “substantially” refers to ranges within 10%, preferably within 5%, more preferably within 1%, and most preferably within 0.5% of what is specified.

The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a method or device that “comprises,” “has,” “includes” or “contains” one or more steps or elements possesses those one or more steps or elements, but is not limited to possessing only those one or more elements. Likewise, a step of a method or an element of a device that “comprises,” “has,” “includes” or “contains” one or more features possesses those one or more features, but is not limited to possessing only those one or more features. Furthermore, a device or structure that is configured in a certain way is configured in at least that way, but may also be configured in ways that are not listed.

Other features and associated advantages will become apparent with reference to the following detailed description of specific embodiments in connection with the accompanying drawings.

### BRIEF DESCRIPTION OF THE DRAWINGS

The following drawings form part of the present specification and are included to further demonstrate certain aspects of the present invention. The invention may be better understood by reference to one or more of these drawings in combination with the detailed description of specific embodiments presented herein.

FIG. 1A is a cross-section view diagram of a p-channel RADFET.

FIG. 1B is a layout view diagram of a p-channel RADFET.

FIG. 2A illustrates a threshold voltage shift in p-channel RADFET, showing negative shift in threshold voltage with increase radiation dose as well as a deleterious impact of interface traps is also illustrated

FIG. 2B is a schematic diagram of a p-channel measurement configuration.

FIG. 3 is a band diagram of MOS system in equilibrium showing main processes in radiation-induced positive charge trapping in SiO₂.

FIG. 4A is a cross-section view diagram of a standard p-type MOSFET.

FIG. 4B is a layout view diagram of a standard p-type MOSFET.

FIG. 5 is a simplified illustration of one embodiment of a radiation sensing capacitor.

FIG. 6 illustrates a pre-irradiation C-V curve obtained from one embodiment of a radiation sensing capacitor.

FIG. 7 illustrates the effect of ionizing total dose on one embodiment of a radiation sensing capacitor's C-V characteristics.

FIG. 8 illustrates a change in capacitance of one embodiment of a radiation sensing capacitor as a function of dose (normalized to pre-rad) for Vgb=0V.

FIG. 9 is a 2D cross-section view diagram of one embodiment of an integrated radiation sensing capacitor.

FIG. 10 is a close-up view diagram of one embodiment of a silicon-insulator interface region showing the charge trapping precursor layer within 50 nm of interface.

FIG. 11 is a 3D illustration of one embodiment of a radiation sensor.

FIG. 12 is a 2D diagram illustrating one embodiment of a radiation sensor.

FIG. 13 is a graphical representation of simulated buildup of oxide trapped charge with respect to dose in the radiation sensor.

FIG. 14 is a simulated silicon capacitance and surface potential with respect to dose for one embodiment of a radiation sensing capacitor integrated in the radiation sensor.

FIG. 15 is a graphical representation of the capacitance of the radiation sensing capacitor with respect to radiation dose.

FIG. 16 is a process flow diagram illustrating one embodiment of a method of manufacturing a radiation sensing capacitor.

FIG. 17 is a process flow diagram illustrating one embodiment of a method of manufacturing a radiation sensing capacitor.

FIG. 18 is a process flow diagram illustrating one embodiment of a method of manufacturing a radiation sensing capacitor.

FIG. 19 illustrates an equivalent circuit of a loop antenna in transmit mode, shown with source and resonant capacitor.

FIG. 20 illustrates an equivalent circuit of one embodiment of a radiation sensor.

FIG. 21 is a graphical representation of the reflection coefficient of the equivalent circuit of FIG. 20.

FIG. 22 is a graphical representation of a Harmonic Balance simulation of one embodiment of a radiation sensing capacitor.

FIG. 23 is a graphical representation of harmonic content of a signal reflected from one embodiment of a radiation sensor.

FIG. 24 is a photograph of system in which one embodiment of the radiation sensor is implemented.

FIG. 25 is a diagram illustrating an embodiment of a flexible skin comprising a plurality of radiation sensors for use in package shipping.

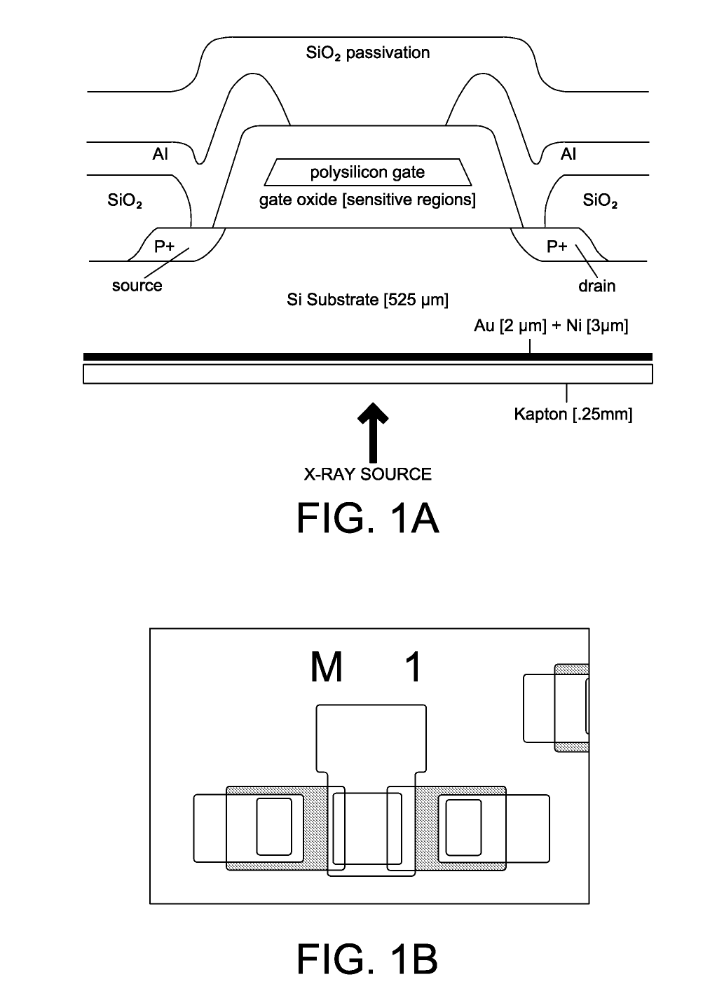

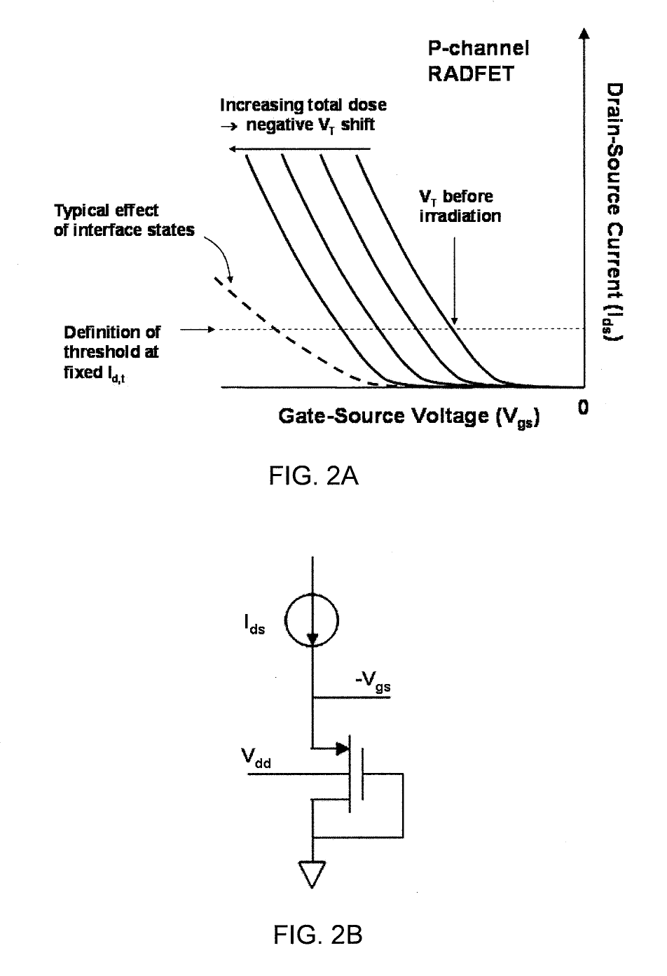

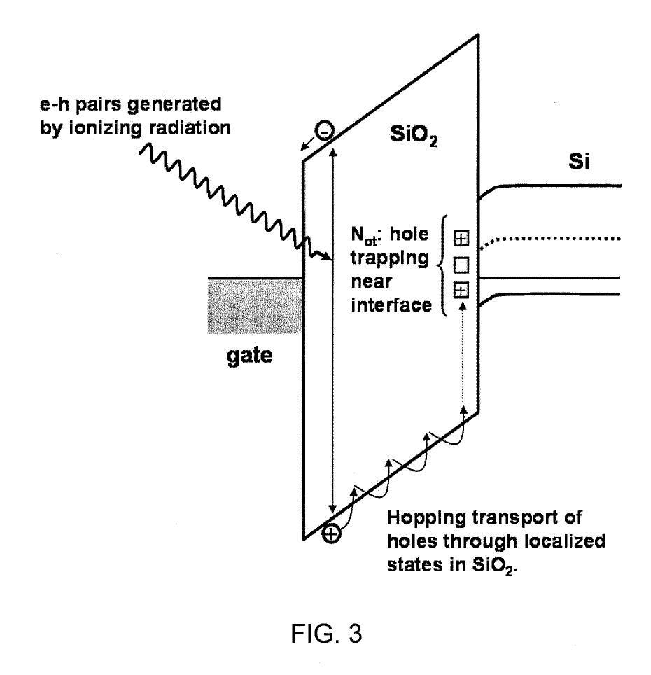

### DETAILED DESCRIPTION

Various features and advantageous details are explained more fully with reference to the nonlimiting embodiments that are illustrated in the accompanying drawings and detailed in the following description. Descriptions of well known starting materials, processing techniques, components, and equipment are omitted so as not to unnecessarily obscure the invention in detail. It should be understood, however, that the detailed description and the specific examples, while indicating embodiments of the invention, are given by way of illustration only, and not by way of limitation. Various substitutions, modifications, additions, and/or rearrangements within the spirit and/or scope of the underlying inventive concept will become apparent to those skilled in the art from this disclosure.

A passive, wireless radiation detector (WRD) capable of measuring cumulative dose from an ionizing radiation source is presented. One embodiment of the described sensor includes a passive LC antenna resonator circuit integrated onto a solid state micro-chip, less than 1 mm in every dimension. Standard semiconductor processing materials may be used in chip fabrication. These may include: crystalline doped silicon, silicon-dioxide, and aluminum metal. Although, the present embodiments describe two specific antenna designs: a conventional loop and a folded patch antenna, one of ordinary skill in the art will recognize alternative antenna configurations. A metal-oxide-silicon (MOS) capacitor may be integrated with the antenna to form the resonating LC circuit. The resonator may receive and reflect the energy from an external radio frequency (RF) source. The measured reflected signal is then used to calculate the capacitance of the network, which is a specially designed to shift negatively upon exposure to ionizing radiation. This radiation sensitive capacitor is called the RADCAP.

Functionally, the integrated LC resonator (RADCAP and inductive antenna) may be illuminated by the external RF source as the signal is swept over narrow band frequencies. The RADCAP may be configured such that the nominal value resonates the loop antenna at the center frequency of the RF sweep. The RADCAP may be a nonlinear device so it may also reflect energy at source frequency harmonics. The reflected full-band frequency response of the on-chip network is recorded by an external receiver. Since the properties of the antenna and chip may be known, the RADCAP capacitance at the antenna terminals may be readily calculated from the return signal spectrum.

The RADCAP may be configured and fabricated to be highly sensitive to ionizing radiation dose. The RADCAP MOS system is comprised of a SiO₂ dielectric film, between 10 nm and 1 μm thick, sandwiched between the aluminum metal (the material which forms the antenna) and a boron doped (10¹⁵ to 10¹⁸ cm⁻³) silicon substrate (50 nm to 100 μm thick). The dielectric may be modified during processing to have a controlled density of hole trapping precursors (such as oxygen vacancies) which become charged upon exposure to ionizing radiation. As charged accumulates in the SiO₂ film during exposure, the surface potential of the underlying silicon is increased thereby shifting the capacitance of the system. Radiation-induced shifts in the RADCAP capacitance are extracted wirelessly from the return signal. The radiation-induced shift in capacitance is used to determine the precise level of cumulative ionizing radiation dose the micro-chip is exposed to at the time of reading. The novelty of the design is in its use of a single MOS capacitor that acts as both a cumulative ionizing radiation dose detector and frequency multiplier.

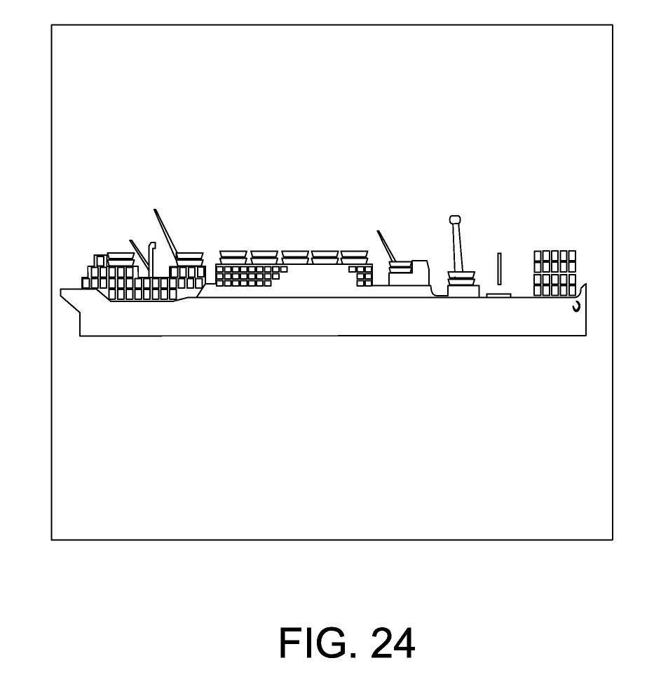

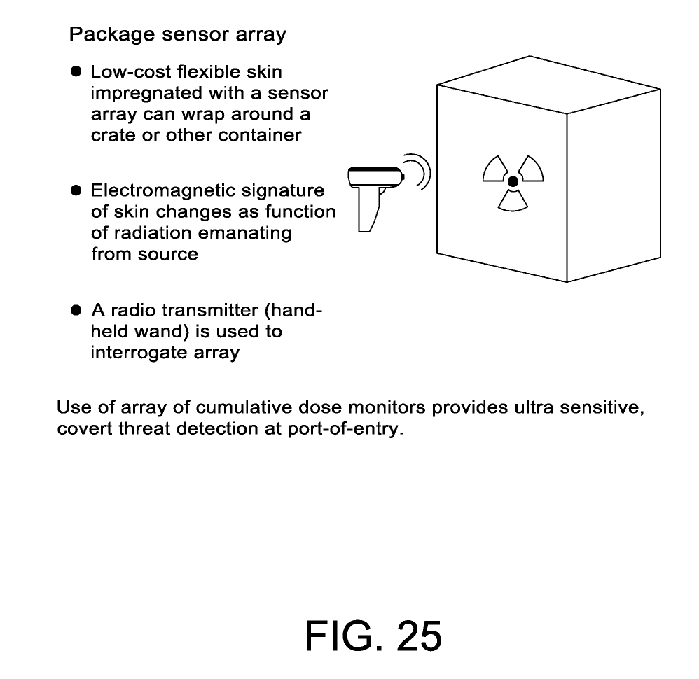

The extremely small size of the device, less that 1 mm in each dimension, enables it to be adapted for a wide range of applications. One particular application is as an implantable dosimeter. The device may be inserted into human tissue with, given its small size, minimal damage to surrounding mass. The implantable device can accurately measure the ionizing dose deposited locally into the body during clinical radiation treatments. An alternative application is the covert detection of radiation sources, such as nuclear or radiological devices, that would be utilized by adversaries as weapons, such a dirty bombs embedded in cargo. These types of weapons represent obvious threats to commercial ports of entry. The extremely small size and low cost of these chips would allow many devices to be added to shipping container coatings where they could effectively detect and report low levels of radiation emission from concealed sources within cargo. For example, the system of FIG. 24 illustrates a shipping system where a plurality of the present radiation sensors may be integrated with shipping containers or embedded within the contents of the shipping containers before or during transit. The sensors 1100 may detect radiation during the course of transit, and then read by an EM reader at port. Alternatively, the devices may be integrated into other low-cost thin skins for shipping and other applications, including paper covers, polymer-based covers, tarps, and the like. One embodiment of a thin skin having a plurality of radiation sensors 1100 is illustrated in FIG. 25.

The radiation sensor may cumulative dose over time, so measurements of radiation dose may be integrated over the entire duration of e.g., a cargo shipment, prior to arrival at the targeted port. The device is therefore significantly more sensitive and costs much less than previously known radiation detection systems. The RF signal receiver wands configured for use with the present radiation sensor may be simple, low cost adaptations of current technologies.

In order to significantly reduce the form factor size the proposed device (described in detail below) is an integrated solid state microchip that occupies an area less than 1 mm² in each dimension. The chip can be fabricated in a low cost standard silicon RFCMOS process. Moreover all the components on the chip are passive devices (requiring no power) to reduce circuit complexity. The primary components of the device are: 1) an on chip loop or patch antenna and 2) a radiation sensing MOS capacitor (RADCAP) dosimeter. The concept, along with examples of devices and processes to make the devices will now be described.

### General Wireless Radiation Detector

With respect to ultra-low-power (ULP) RF telemetry, there are several distinctions between the use of a RADCAP and a RADFET. In a RADFET application, similar to that presented in (5), the dosimeter, energy harvesting, and data transmission circuitry are all distinct blocks. This significantly increases the application complexity and furthermore makes it difficult to be realized as fully integrated, low-cost micro-device. For the RADFET application, energy harvesting is achieved via conventional LC tank resonance and rectification to generate the DC power to the dosimeter and support circuitry (ADC, ASIC state machine, memory, etc.). In the architecture now described, the “C” in the LC tank resonator is the dosimeter, the RADCAP. As will be discussed below, the magnitude of the RADCAP capacitance is a function of total ionizing dose. Therefore if the RADCAP capacitance can be measured, the dose deposited at that location is known. In certain described embodiments, the RADCAP creates of single input mixer capable a transmitting harmonic signatures out to an external reader (e.g. a network analyzer). The resonant frequency of the received second harmonic will enable the magnitude of the RADCAP to be sensed, and therefore dose measured. This may remove the need for additional active on-chip support circuitry, thereby reducing power and area requirements.

### RADCAP Dosimeter

The RADCAP may include a MOS capacitor fabricated according to a modified silicon CMOS flow. As the cross-section in 4a indicates, the device may be composed of a degenerately doped n-type polysilicon gate deposited onto a radiation sensitive SiO₂ gate oxide layer. The gate oxide is thermally grown or deposited over a p-type silicon substrate.

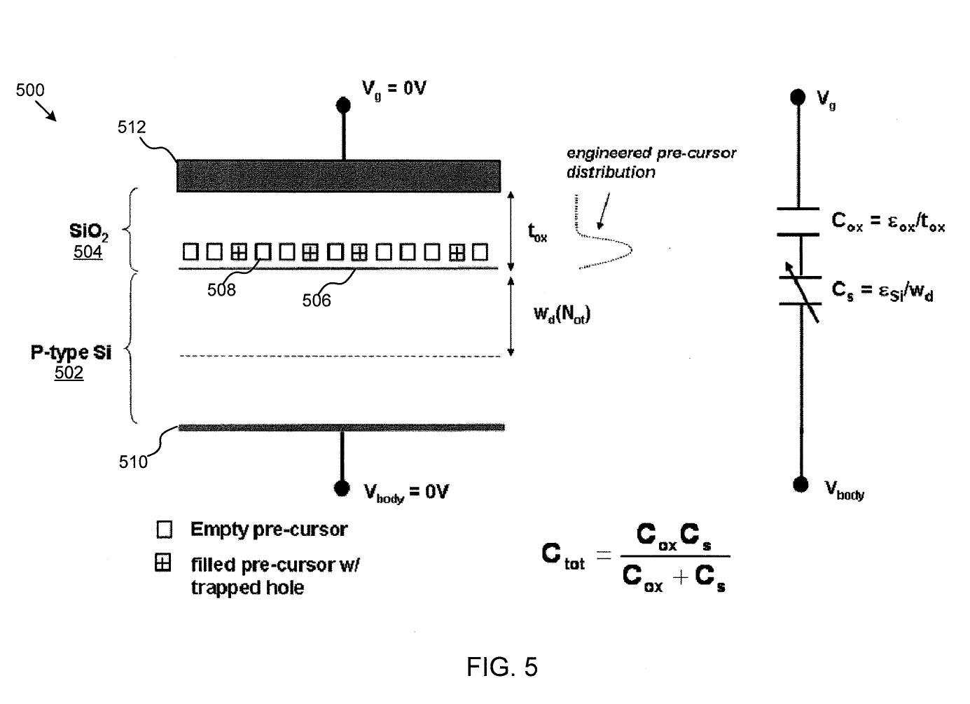

A simplified diagram of the MOS capacitor is illustrated in FIG. 5. One embodiment of a radiation sensing capacitor 500 is presented. The radiation sensing capacitor 500 may include a silicon layer 502 and an insulator layer 504 coupled to the silicon layer 502. The radiation sensing capacitor 500 may also include a silicon-insulator interface region 506 coupling the silicon layer 502 to the insulator layer 504 and a plurality of hole-trapping precursors 508 formed in the insulator layer 504 proximate to the silicon-insulator interface region 506.

In one embodiment, the plurality of hole-trapping precursors 508 include oxygen vacancies. In another embodiment, the plurality of hole-trapping precursors 508 may include nano-cluster trapping sites. The insulator layer 504 may include silicon dioxide SiO₂. Also, the silicon layer 502 comprises p-type doped silicon.

In a further embodiment, the radiation sensing capacitor 500 may include a first conductor coupled to the silicon layer 502, and a second conductor coupled to the insulator layer 504. The first conductor and the second conductor may be composed of aluminum (Al).

The figure shows that the gate oxide is engineered so that the majority of the hole-trapping pre-cursors are located near the Si/SiO₂ interface (<50 nm). These precursors 508 may be oxygen vacancies, but may also be specially engineered trapping sites such as nano-clusters. The density and distribution of these trapping sties 508 can be controlled by oxide growth conditions. These conditions include processing times and temperatures as well as careful control of the molecular oxygen and hydrogen content in the oxide forming gas. The development of well-tuned processing recipes are currently being developed at the Center for Solid State Electronics Research (CSSER) at Arizona State University [6]. As with RADFET dosimeters, the pre-cursor density and distribution in the RADCAP oxide as well as their trapping cross-section are key parameters in damage factor constant, a, discussed above.

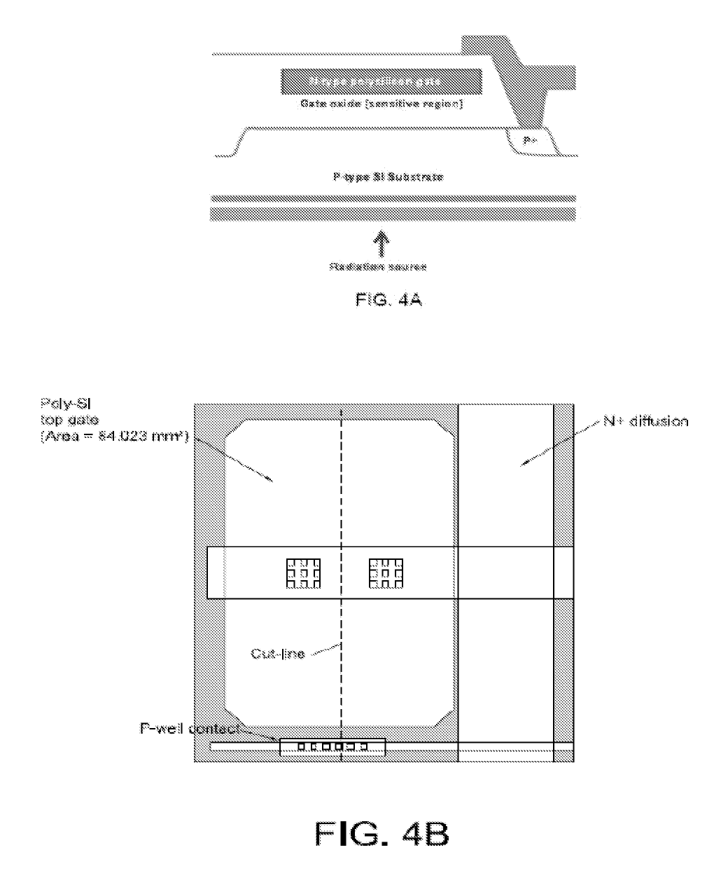

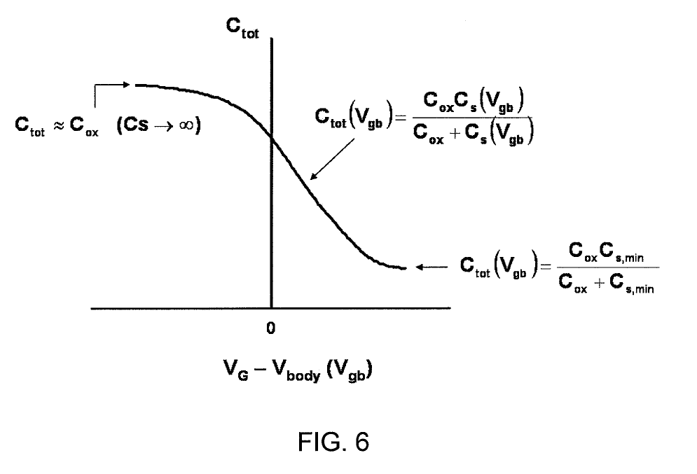

The primary response characteristic of an example of the MOS capacitor is the capacitance-voltage (C-V) illustrated in FIG. 6. This curve was obtained from pre-irradiation experimental measurements on p-substrate MOS capacitors fabricated in a standard commercial 130 nm CMOS process. The layout of the capacitor is provided in FIG. 4b. FIG. 5 shows that the total areal capacitance of the MOS capacitor (F/cm²), Cₜₒₜ, is the series combination of two capacitors: the fixed oxide (Cₒₓ) and the oxide-charge-sensitive silicon (Cₛ). For a p-substrate device, large negative dc gate-to-body biases will cause the total capacitance to asymptotically approach Cₒₓ. The negative bias accumulates the silicon surface, shrinking the depletion region width (w_{d}) to zero, thereby causing the Cₛ to become infinitely large (see equation of Cₜₒₜ in FIG. 5). As the gate-to-body bias is increased a depletion (space-charge) layer is formed in the silicon near the Si/SiO₂ interface. The differential capacitance across this layer can be expressed as

$${C}_{s} ( {V}_{gb} ) = \frac{\partial Q}{\partial {ψ}_{s}} \approx \frac{{ɛ}_{Si}}{{w}_{d} ( {V}_{gb} )} , \qquad ( 4 )$$

where ∂Q is the change in space-charge with a corresponding change in potential in the silicon under-layer (∂ψₛ). The variable ψₛ is called the surface potential. For increasing dc gate-to-body biases, the depletion region width increases, thereby reducing the Cₛ (see Eq. 4). Cₛ and the total capacitance reach a minimum when the surface potential, and therefore the depletion width is maximized. The gate-to-body voltage is approximately equal to near the device threshold voltage at this minimum point.

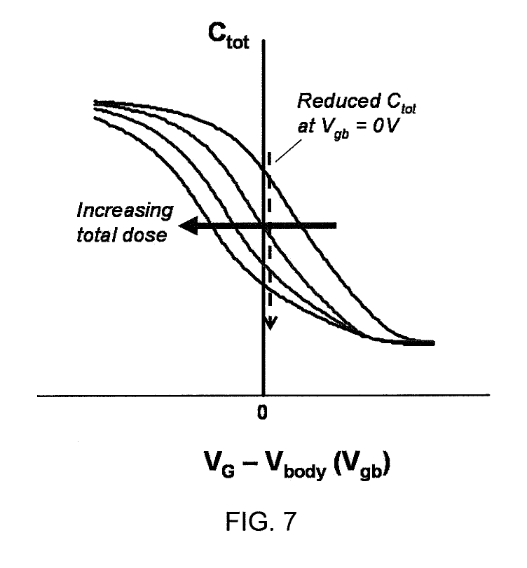

FIG. 7 shows how ionizing radiation alters the C-V curve. These results were obtained from experiments on the same 130 nm MOS capacitors. The results shows as negative voltage shift in the C-V characteristics and a reduction in the total capacitance at a fixed V_{gb} (e.g. at V_{gb}=0V). Like the RADFET, the MOS capacitor (RADCAP) can also act as a radiation sensor. The primary difference being that the radiation signature can be accessed via a sampling of capacitance, which unlike the RADFET requires no static DC power during the read-out. Our zero-static power read-out approach will be presented in the following section.

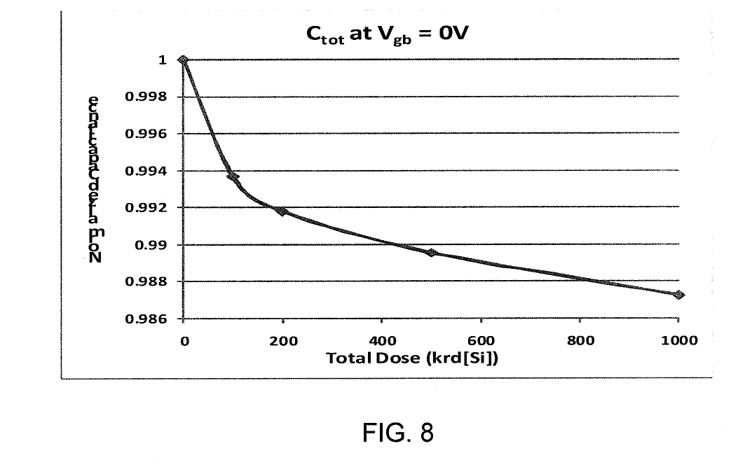

The mechanisms for the negative shift in the C-V curves are as follows. Radiation-induced holes generated in the sensitive oxide are trapped in the pre-cursors during exposure. The resulting trapped positive charge near the interface increases the surface potential (and w_{d}) in the underlying silicon, thereby decreasing Cₛ and Cₜₒₜ at each gate-to-body bias point. For this discovery, no static dc gate-to-body bias is applied during exposure (write stage) or during the read stage (requirements 4 and 5), thus it is the change in Cₜₒₜ at V_{gb}=0V which is the radiation signature. For the MOSCAP data shown in FIG. 7, the response is plotted in FIG. 8.

Assuming the change in Cₜₒₜ can be sampled wirelessly, off chip, the dose incident on the RADCAP will be able to be obtained via the following procedure.

### RADCAP Dose Extraction Procedure

Known constants: Cₒₓ, p-type body/substrate doping (N_{A}), body effect coefficient (γ), silicon permittivity (∈_{Si}), SiO₂ permittivity (∈ₒₓ), electron charge (q).

Given the total capacitance, Cₜₒₜ, at V_{gb}=0V

$${C}_{s} = \frac{1}{1 / {C}_{tot} - 1 / {C}_{ox}} . \qquad ( 5 )$$

The surface potential can obtained from Cₛ with the equation

$${ψ}_{s} = \frac{q {ɛ}_{Si} {N}_{A}}{2 {C}_{s}^{2}} . \qquad ( 6 )$$

Using the implicit equation for surface potential, the post-irradiated increase in Nₒₜ above the pre-rad level can be calculated as

$$Δ {N}_{ot} = \frac{{C}_{ox}}{q} [ {ψ}_{s , post} - {ψ}_{s , pre} + γ ( \sqrt{{ψ}_{s , post}} - \sqrt{{ψ}_{s , pre}} ) ] . \qquad ( 7 )$$

and from (2) the dose may be calculated.

### Capacitor Structure

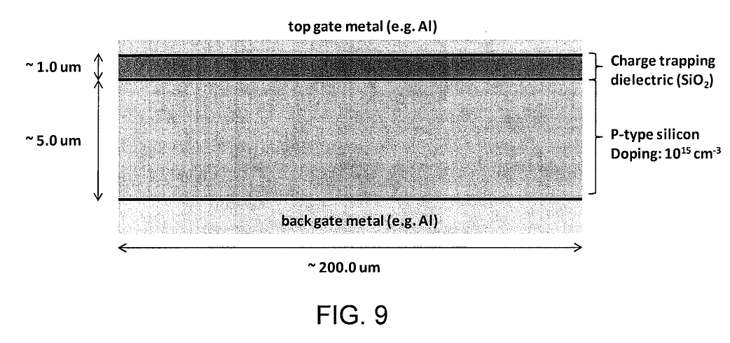

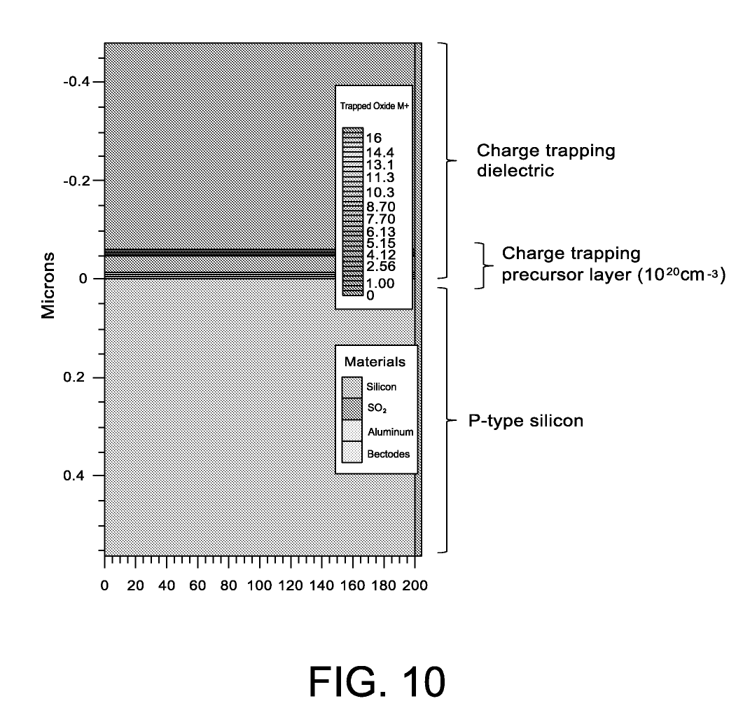

FIG. 9 is a representative 2-D cross-section of an exemplary RADCAP. As the figure illustrates, a 1.0 um thick charge trapping dielectric material covers a p-type silicon (Si) layer, which is 5.0 μm thick. The acceptor species added to the Si bulk are boron atoms uniformly doped to a proposed concentration of between 10¹⁴ and 10¹⁶ cm⁻³. The current design has a boron concentration of 10¹⁵ cm⁻³. The metal gate material, which also forms the patch antenna, is aluminum (Al) but other materials are being investigated. The proposed dielectric is deposited or thermally grown SiO₂, however composite films (e.g. oxide-nitride stacks) are also being considered for the RADCAP. Hole trapping precursors such as oxygen vacancies or traps located at dielectric stack interfaces are added to the dielectric within 50 nm of the Si interface (see FIG. 10). The proposed density of precursors is centered at 10²⁰ cm⁻³. A strict tolerance on the hole trap density is not critical, i.e., a process that creates precursors in the range of 10¹⁸-10²¹ cm⁻³ is acceptable, but the level will depend on dosimeter requirements such as maximum dose range and resolution. Effective trapping cross-sections for the precursors can range between 10⁻¹³ and 10⁻¹⁵ cm², which correlates to the levels found in literature [reference]. The current version uses a cross-section of 10⁻¹⁴ cm². For this structure the vertical electric field in the dielectric is ˜10³ V/cm when 0V are applied across the top and back gates. This will give a hole yield of slightly less than 10% [ref my paper in TNS].

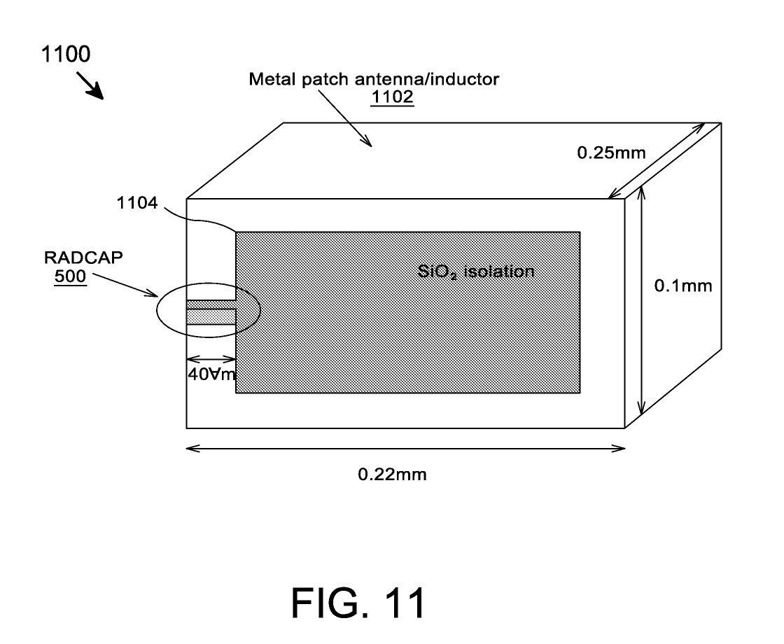

A radiation sensor 1100 is illustrated in FIG. 11. In one embodiment, the radiation sensor 1100 includes a radiation sensing capacitor 500 and an antenna 1102 coupled to the radiation sensing capacitor 500. The radiation sensing capacitor 500 may include a silicon layer 502 and an insulator layer 504 coupled to the silicon layer 502. The radiation sensing capacitor 500 may also include a silicon-insulator interface region 506 coupling the silicon layer 502 to the insulator layer 504 and a plurality of hole-trapping precursors 508 formed in the insulator layer 504 proximate to the silicon-insulator interface region 506.

In a further embodiment, the radiation sensor 1100 may also include an isolation block 1104, wherein the antenna 1102 is formed around the isolation block 1104. In particular, the antenna 1102 may be a patch antenna 1102. In such an embodiment, the antenna 1102 may be made of, e.g., aluminum (Al). The antenna 1102 may include a first contact portion 510 and a second contact portion 512, wherein the first contact portion 510 is coupled to the silicon layer 502 and the second contact portion 512 is coupled to the insulator layer 504.

In a further embodiment, the radiation sensor 1100 may include a plurality of radiation sensing capacitors 500 arranged such that each of the plurality of radiation sensing capacitors 500 are selectably coupled to the antenna 1102. For example, each radiation sensing capacitor 500 may be coupled to a shorting pin formed through the insulator layer 504.

In one embodiment, the radiation sensor 1100 is configured to reflect a response signal having a primary frequency and a plurality of harmonic frequencies in response to interrogation from a remote radio-frequency source. The primary frequency and the harmonic frequencies may be determined by a level of radiation sensed by the radiation sensing capacitor 500.

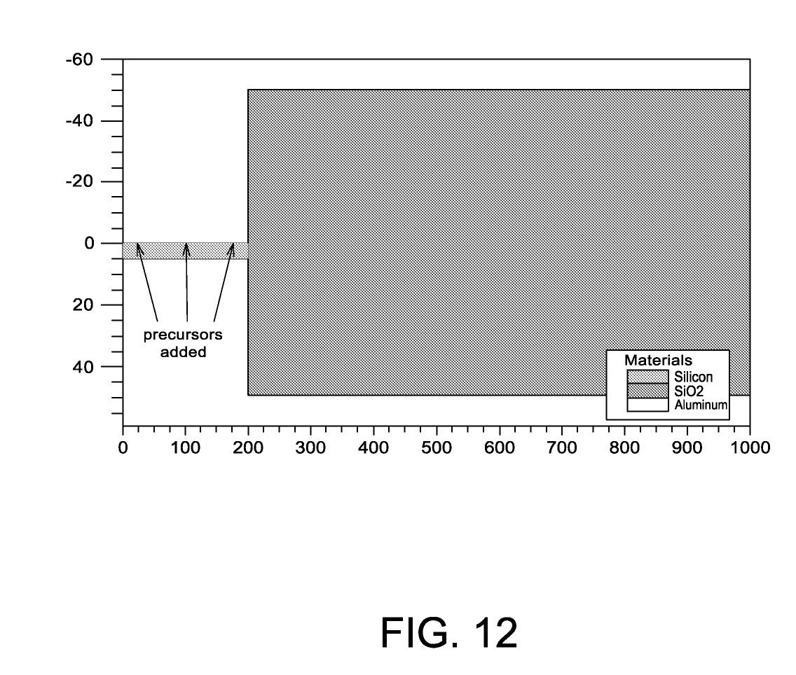

FIG. 12 shows how the exemplary RADCAP is integrated into an exemplary patch resonator loop structure. As the figure illustrates, the dimensions of the complete loop device are well below 1 mm³. The RADCAP is embedded in the patch loop on one side and isolated from the rest of the metallization with a thick layer of SiO₂ dielectric. In subsequent sections, a fabrication process for the CLPR device is provided as well as a detailed description of device operation, supported by the results of electro-magnetic simulations.

### Modeling Results

Ionizing-radiation-enabled TCAD simulations using were performed on a 2D structural representation of the CLPR device (FIG. 12). A density of oxide charge trapping precursors (Nₜ=10²⁰ cm³) were added to the RADCAP dielectric uniformly in the film less than or equal to 50 nm from the RADCAP silicon interface (see FIG. 10). The hole capture cross-section for the precursors was fixed to 10⁻¹⁴ cm². The oxide thickness was set to 1.0 μm.

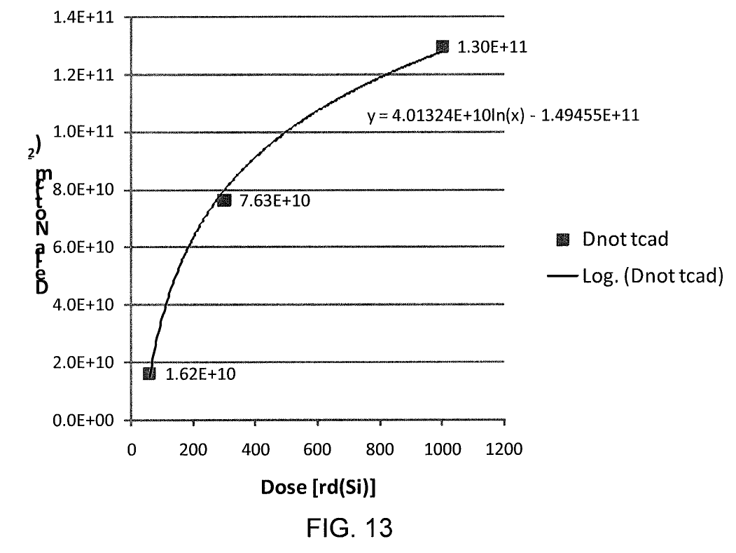

FIG. 13 plots the simulated buildup of oxide trapped charge (projected to the interface) for various levels of dose exposure. The data may be fit to a logarithmic response function as shown.

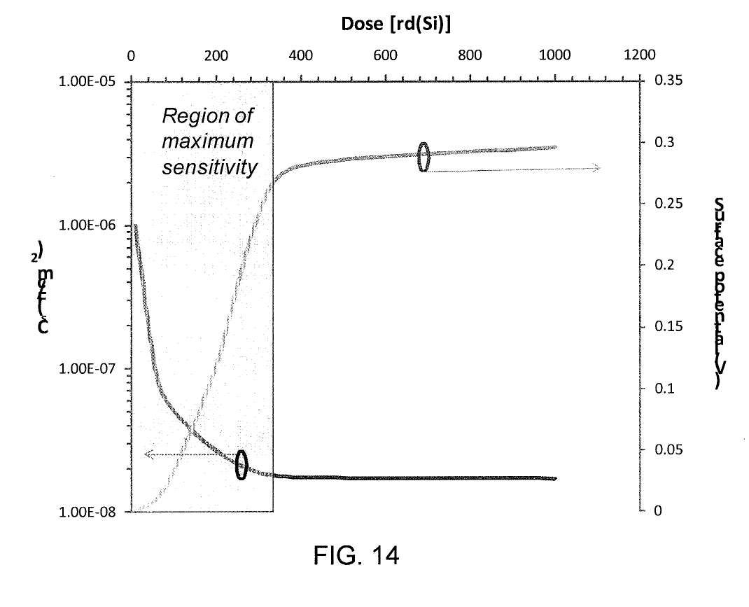

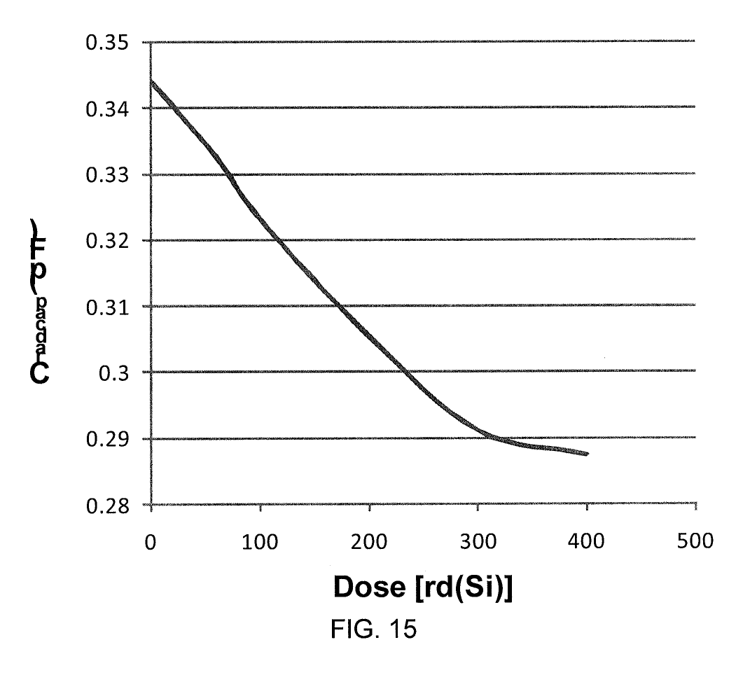

FIG. 14 plots the simulated RADCAP silicon capacitance (Cₑ) and surface potential (ψₛ) vs. dose (at V_{gb}=0V) for the CLPR device. For the current device design the region of maximum sensitivity ranges from zero to ˜340 rd(Si). This region may be controlled via process modifications to RADCAP oxide thickness, doping, and precursor densities. The current design give a maximum surface potential to dose sensitivity of 1.2 mV per rd(Si).

As noted in the description above, ionizing radiation induced shifts in Nₒₜ, ψₛ, and Cₛ cause monotonic reductions in the total RADCAP capacitance, C_{radcap}, which is value measured wireless by the sensor. FIG. 14 plots the results of simulations on the CLPR showing C_{radcap} vs. dose. The plot is similar to the experimental data in FIG. 8, although, as a comparison of the plots shows, the RADCAP is (as designed) much more sensitive to dose. The RADCAP capacitance sensitivity is on the order of 0.05% change in capacitance per rad, which means that if the detector can reliably resolve at least 1% changes in loop capacitance than the device will have a resolution of 20 rd(Si). This sensitivity would allow for the detection of a source emitting radiation at very low rate of 0.1 mrd/s if the sensing is occurring over a 1 week period (e.g., the time it would take a cargo shipment to be transported from overseas to a U.S. port).

### Fabrication Process

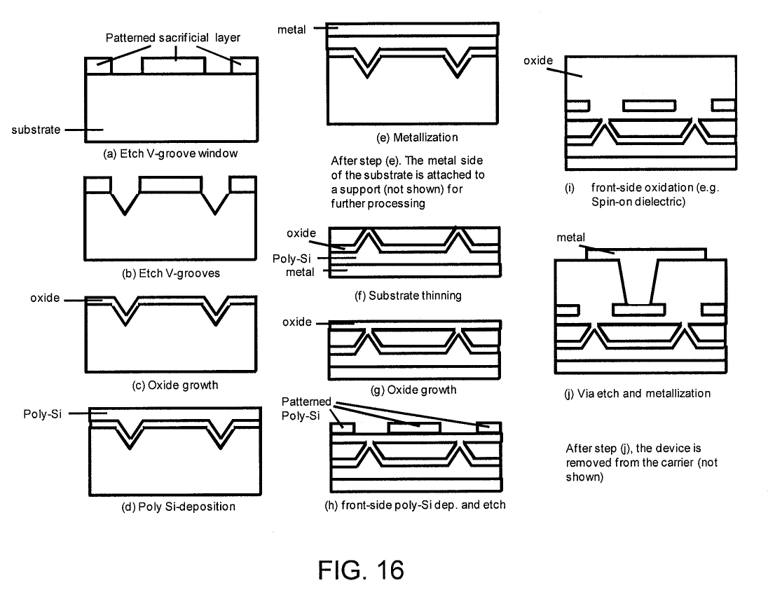

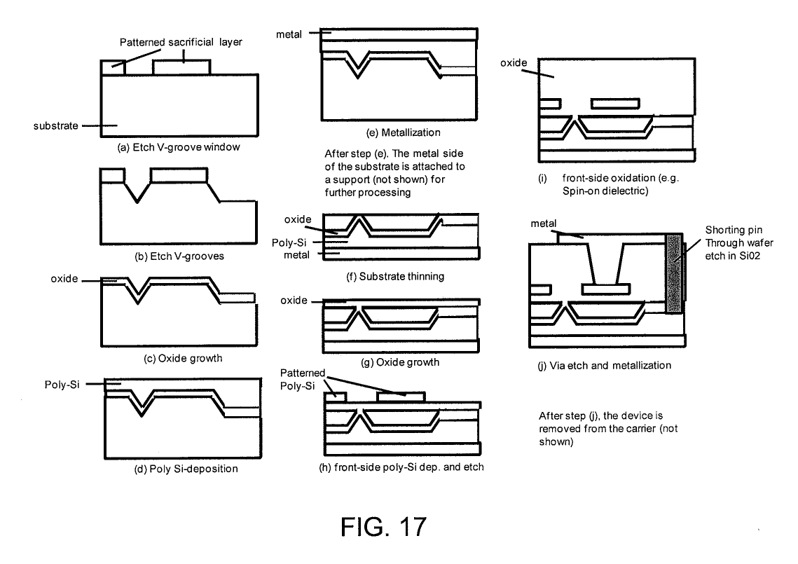

A method of manufacturing a radiation sensor 1100 is illustrated in FIG. 16. In one embodiment, the method includes forming a silicon layer 502, forming an insulator layer 504 coupled to the silicon layer 502 such that a silicon-insulator interface region 506 couples the silicon layer 502 to the insulator layer 504, and forming a plurality of hole-trapping precursors 508 formed in the insulator layer 504 proximate to the silicon-insulator interface region 506.

In one embodiment, forming a silicon layer 502 may include providing a silicon substrate having a sacrificial layer formed thereon, etching the sacrificial layer to provide a one or more groove windows, etching one or more grooves into the substrate through the grove windows of the sacrificial layer, removing the sacrificial layer, forming a layer on a first surface of the silicon substrate and in the one ore more grooves, and reducing the thickness of the silicon substrate from a second surface opposite the first surface until at least a portion of the oxide layer formed in the one or more grooves is exposed through the second surface.

The method may also include forming a polysilicon layer 502 on the oxide layer, and forming a metal layer over the polysilicon layer 502. In a particular embodiment, forming the insulator layer 504 may include forming the insulator layer 504 on the second surface.

Additionally, the method may include forming a patterned poly-silicon layer 502 in the insulator layer 504, and forming a metal contact with the poly-silicon layer 502 through the insulator layer 504. The method may also include coupling the silicon layer 502 and the insulator layer 504 to an antenna 1102.

The technology targeted for device fabrication is silicon-on-insulator (SOI). A process which is a modification of mature dielectric isolation (DI) technologies, as described by Kasai et al., Tech Dig. IEDM, 1985, p 419, may be used. A summary of an exemplary process flow is show in FIG. 16.

In the exemplary embodiment described, the substrate is a (100 oriented) p-doped silicon substrate. The exemplary process is as follows:
(a) Define, using photolithography, groove windows in a sacrificial layer. The sacrificial layer can be photoresist, or a dielectric such as SiO₂ or a combination of resist and dielectric. The thickness of the sacrificial layer and the width of the groove windows can be varied. The width of the windows can be of the order of approximately a few μm to a few 100's of μm wide. The pitch between the grooves can range from approximately several 10s of μm to a few hundred The length of the grooves (perpendicular to the plane of the image) can be between approximately 10 and 300 μm. The thickness of the sacrificial layer is chosen to allow etching to occur in the Silicon only where it is exposed.
(b) Etch the V-grooves: this can be achieved using a selective etch to remove the silicon only. The etch is an anisotropic etch. The depth of the groves may range between approximately 1 and 20 μm.
(c) After removal of the sacrificial layer, an approximately 1 μm thick silicon oxide (SiO₂) layer is formed on the top surface of the wafer using any known oxidation method. The oxide growth can be controlled in order to produce a desired number of defects. Typically, it can be a thermal growth, with a small amount of hydrogen introduced into the process. The partial pressure of the hydrogen is greater than about 0.01%. Instead of just SiO₂, a stack of thermal oxide (SiO₂) under a CVD deposited nitride may also be deposited (reference Schwank. IEEE TNS vol 43 issue 6 1996).
(d) A poly-Si layer is deposited. This can be achieved through sputtering, low pressure chemical vapour deposition, or other techniques. Planarization (such as chemical mechanical polishing (CMP)) can be used on the surface to reduce roughness.
(e) A planar metal layer is formed on the poly-Si layer. The metalized side of the wafer is then temporarily attached/bonded to a carrier to take it through the remaining process steps.
(f) The substrate is then lapped to thin it. The wafer is thinned until the oxide in the groove is exposed. This thinning can be achieved using mechanical and/or chemical techniques.
(g) A thermal oxidation is performed to cover the exposed Si and SiO₂. The oxide growth can be controlled in order to produce a desired number of defects. Typically, it can be a thermal growth, with a small amount of hydrogen introduced into the process. The partial pressure of the hydrogen is greater than about 0.01%. At least one of the thermal oxidation steps ((c) and (g) should introduce defects in a controlled manner. An oxide/nitride stack (referred to in step (c)) can also be used.
(h) A poly-Si layer is then deposited. This can be achieved through sputtering, low pressure chemical vapour deposition, or other techniques. It is patterned using lithography, and a selective etch to remove the poly-Si in regions where the photoresist is removed is performed. After etching, the resist is removed (e.g. using solvents, ashing).
(i) SiO₂ is then deposited on the patterned poly-Si layer. This can be achieved through sputtering, low pressure chemical vapour deposition, or other techniques such as a spin-on (sol-gel method). A combination of processes can be used. The thickness of this layer can be approximately 100 μm or larger. Lithography is then performed on the top surface and a via etch is made above regions of the poly-Si. Metal is then deposited in the etched wells, and contacts the poly-Si layers. The metal is then patterned on the top surface. In some cases the metal is patterned to optimized antenna performance. In most case the metal may be simply evaporated onto the wafer. The carrier is then removed, and dicing can be used to form individual devices.

In some embodiments, SiO₂ could be replaced by Silicon nitride, silicon oxynitride, or a multi-layer dielectric stacks with materials chosen from SiO2, silicon nitride, and silicon oxynitride.

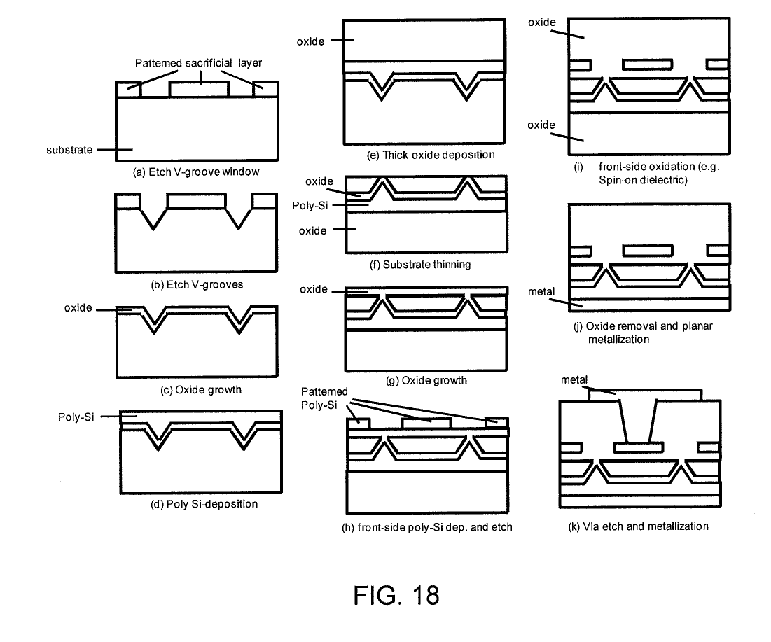

The above process can be modified. FIG. 18 shows a process flow to make an exemplary RADCAP with a shorting pin. At the via etch and metallization stage (step j), an etch can also be made to the lower poly-Si layer and a shorting pin can be formed.

The exemplary process shown in FIG. 18 is as follows:
(a) Define, using photolithography, groove windows in a sacrificial layer. The sacrificial layer can be photoresist, or a dielectric such as SiO₂ or a combination of resist and dielectric. The thickness of the sacrificial layer and the width of the groove windows can be varied. The width of the windows can be of the order of approximately a few μm to a few 10's of μm wide. The pitch between the grooves can range from approximately several 10s of μm to a few hundred μm. The length of the grooves (perpendicular to the plane of the image) can be between approximately 100 and 300 The thickness of the sacrificial layer is chosen to allow etching to occur in the Silicon only where it is exposed.
(b) Etch the V-grooves: this can be achieved using a selective etch to remove the silicon only. The etch is an anisotropic etch.
(c) After removal of the sacrificial layer, an approximately 1 μm thick oxide layer is formed on the top surface of the wafer using any known oxidation method. The oxide growth can be controlled in order to produce a desired number of defects. Typically, it can be a thermal growth, with a small amount of hydrogen introduced into the process. The partial pressure of the hydrogen is greater than about 0.01%.
(d) A poly-Si layer is deposited. This can be achieved through sputtering, low pressure chemical vapour deposition, or other techniques. Planarization (such as chemical mechanical polishing (CMP)) can be used on the surface to reduce roughness.
(e) SiO₂ is then deposited on the poly-Si layer. This can be achieved through sputtering, low pressure chemical vapour deposition, or other techniques such as a spin-on (sol-gel method). A combination of processes can be used. The thickness of this layer can be approximately 100 μm or larger.
(f) The substrate is then lapped to thin it. The wafer is thinned until the oxide in the groove is exposed. This thinning can be achieved using mechanical and/or chemical techniques.
(g) A thermal oxidation is performed to cover the exposed Si and SiO₂. The oxide growth can be controlled in order to produce a desired number of defects. Typically, it can be a thermal growth, with a small amount of hydrogen introduced into the process. The partial pressure of the hydrogen is greater than about 0.01%. At least one of the thermal oxidation steps ((c) and (g) should introduce defects in a controlled manner.
(h) A poly-Si layer is then deposited. This can be achieved through sputtering, low pressure chemical vapour deposition, or other techniques. It is patterned using lithography, and a selective etch to remove the poly-Si in regions where the photoresist is removed is performed. After etching, the resist is removed (e.g. using solvents, ashing).
(i) SiO₂ is then deposited on the patterned poly-Si layer. This can be achieved through sputtering, low pressure chemical vapour deposition, or other techniques such as a spin-on (sol-gel method). A combination of processes can be used. The thickness of this layer can be approximately 100 μm or larger.
(j) The SiO₂ deposited in step (e) is removed, and a planar metal layer is deposited, using any known metallization technique, such as sputtering, e-beam deposition, thermal evaporation etc.
(k) Lithography is then performed on the top surface and a via etch is made above regions of the poly-Si. Metal is then deposited in the etched wells, and contacts the poly-Si layers. The carrier is then removed.

An alternative to step (j) in the above process is to perform lithography on the bottom surface, and make a via etch. Metal is then deposited in the etched wells, and contacts the poly-Si layers, akin to step (k). Thus, the metallization process takes place in two steps (one for front-side, one for back side).

The above process can be modified. At the via etch and metallization stage (step k), an etch can also be made to the lower poly-Si layer and a shorting pin can be formed.

Once a wafer has been made, it can be cleaved to form individual devices. In these devices, which can be approximately 0.5 mm by 0.5 mm, it is possible to vary the device capacitance by choosing which of the connections to the poly-Si layer, formed using the via etching, are connected to an external circuit. Varying the capacitance this way results in a variation of the resonance frequency of a circuit, and thus it is possible to produce many devices with different capacitances, with non-overlapping frequency responses. These can then be used as a form of identification in some applications, allowing different devices with different characteristics to be placed in different locations. This can aid the ease of measurement of the radiation dose received in different regions where the RADCAPs are used.

### Capacitively-Loaded Patch Resonator

This radiation sensor 1100 may detect ionizing radiation dosage in cancer treatment. The method consists of implanting a passive chip in the tissue that is dosed. An embodiment of the sensor 1100 may include a printed loop antenna 1102 that is loaded with a MOS capacitor 500. The capacitor 500 may act as the ionizing radiation detector and also a frequency multiplier. The chip is illuminated by sweeping an RF source over a very narrow band. The capacitor may be configured such that the nominal value resonates the loop antenna at the center frequency of the RF sweep, but the exact value of the capacitance at the antenna terminals is a function of ionizing radiation dosage. As the source sweeps over the band, the implanted chip receives the energy and reflects it back out of the loop antenna. A MOS capacitor is a nonlinear device so it will reflect energy not only the frequency of the source, but also at harmonics of the source. The second harmonic is recorded by a receiver. The peak of this recorded reflection will be at the frequency of resonance. Since the properties of the antenna and chip are known, the capacitance at the antenna terminals is easily calculated from the resonance frequency. This capacitance, in turn, is used to find the exact ionizing radiation dose. The novelty of the design is in using a single MOS capacitor to act as both an ionizing radiation detector and frequency multiplier.

### Antenna Design

The design begins with physical size constraints. Currently, the size of the ionizing radiation sources that are implanted in the tissue are on the order of 1 mm squared. The same size will be used for the dosimeter chip for ease of implantation. The antenna will consist of a square loop printed on-chip surrounding the circuitry. The thickness of the chip is determined by the semiconductor chip fabrication process.

The frequency of operation is constrained by current RF technology and also by the FCC. The first consideration was that of the Medical Implant Communication Service (MICS) band [7]. The MICS band is 402-405 MHz. These frequencies have propagation characteristics conducive to the transmission of radio signals within the human body. Also, the MICS band is compatible with international frequency allocations. Operation in the MICS band is permitted by rule and without an individual license issued by the FCC [7]. Unfortunately, MICS devices use transceivers that work by using coded digital transmissions. Transmission protocols are heavily regulated and the band is not free use.

A better solution is to operate within the Industrial, Scientific, and Medical (ISM) radio bands. These bands were originally reserved internationally for the use of RF electromagnetic fields for purposes other than communications. They are less regulated bands and communications equipment must generally accept interference generated by ISM equipment. The domestic ISM bands are stated in the table below [8].

TABLE 1
ISM Band Frequency Allocations.

| | |
|---|---|
| Frequency Range | Center Frequency |

| | | | |
|---|---|---|---|
| 6.765-6.795 | MHz | 6.780 | MHz |
| 13.553-13.567 | MHz | 13.560 | MHz |
| 26.957-27.283 | MHz | 27.120 | MHz |
| 40.66-40.70 | MHz | 40.68 | MHz |
| 902-928 | MHz | 915 | MHz |
| 2.400-2.500 | GHz | 2.450 | GHz |
| 5.725-5.875 | GHz | 5.800 | GHz |
| 24-24.25 | GHz | 24.125 | GHz |
| 61-61.5 | GHz | 61.25 | GHz |
| 122-123 | GHz | 122.5 | GHz |
| 244-246 | GHz | 245 | GHz |

Throughout the design, these ranges of frequencies will be considered with respect to antenna efficiency, attenuation in tissue, and availability of technology.

### Antenna Analysis

As described previously, the antenna is a square loop antenna printed on-chip. The length of the side of the square is 1 mm. This dimension is dictated by compatibility with current implants used in nuclear medicine. The following design example will use the ISM band center frequency of 915 MHz, but the same procedure is valid for any frequency. Results will be shown for multiple ISM center frequencies.

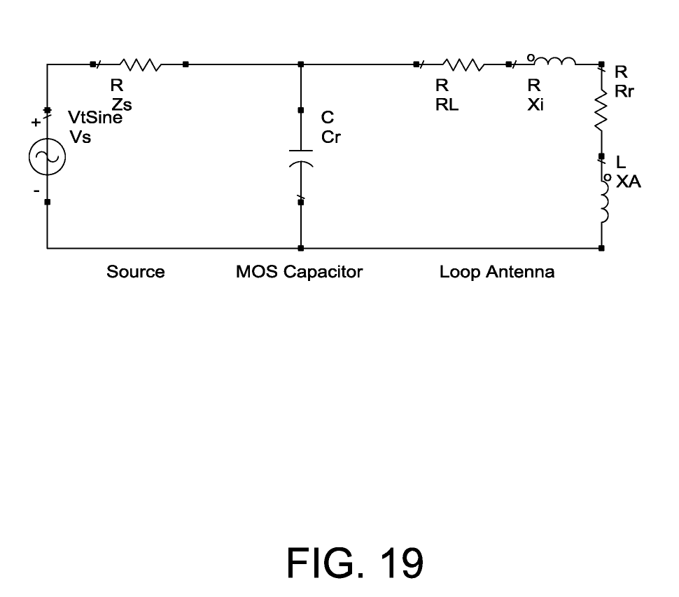

The dimensions of the printed square loop antenna are significantly smaller than the operating wavelength. Therefore, this antenna can be considered a “small loop” for analysis purposes from [9]. Another term commonly used is “Electrically Small Antenna (ESA).” An equivalent circuit of a small loop antenna in transmit mode is shown in FIG. 19.

In this model, Rᵣ, represents the radiation resistance, R_{L} the loss resistance, X_{A} is the external inductive reactance of the loop antenna, and Xᵢ is the internal high-frequency reactance of the loop conductor.

The method of finding these antenna constants is well known and documented in [9]. First some assumptions must be made. It is safe to assume that the tissue surrounding the implant is non-magnetic material. Though it does have dielectric properties, these first order calculations do not take them into consideration. The simulations will show proof of concept, though exact component values may differ slightly. Also, since the loop antenna will be printed on-chip using a silicon process that has yet to be determined, an aluminum metallization layer with a thickness of 28,100 Angstroms is used. This thickness is consistent with many fabrication processes currently offered by IC foundries. The calculations are shown below for an ISM center frequency of 915 MHz, where “t” is the metallization thickness, “a” is the length of the side of the square loop, and “b” is the radius of the “wire” in the printed circuit. It is approximated as half the metallization thickness.

| | | |
|---|---|---|
| ${L}_{A} := 2 \cdot {μ}_{0} \cdot \frac{1 \cdot {10}^{- 3}}{π} \cdot ( ln ( \frac{a}{b} ) - 0.774 )$ | L_{A} = 4.635n | External inductance of square loop antenna. |
| ${L}_{i} := \frac{a}{ω \cdot b} \cdot \sqrt{\frac{ω \cdot {μ}_{0}}{2 \cdot σ}}$ | Lᵢ = 1.252n | Internal inductance of loop with a single turn. |
| Lₜ := L_{A} + Lᵢ | Lₜ = 5.887n | Total loop antenna inductance |
| Xᵢₙ := ω · Lₜ | Xᵢₙ = 33.847 | Input Reactance of the loop antenna |
| ${R}_{r} := {η}_{0} \cdot \frac{{( 2 π )}^{3}}{3} \cdot \frac{{a}^{4}}{{λ}^{4}}$ | Rᵣ = 2.696 × 10⁻⁶ | Radiation Resistance of the loop antenna |
| [symbol] := 4 · a | | The length of the wire that forms the |
| | | loop, ie. the perimeter of the loop. |
| P := 4 · t | | The perimeter of the cross section of the |
| | | wire that forms the loop, ie. the |
| | | circumference of the metalization cross |
| | | section at one place. |
| ${R}_{L} := \frac{L}{P} \cdot \sqrt{\frac{ω \cdot {μ}_{0}}{2 \cdot σ}}$ | R_{L} = 3.6 | Loss Resistance of the loop antenna |
| Rᵢₙ := Rᵣ + R_{L} | Rᵢₙ = 3.6 | Input resistance of the loop antenna |

These calculations should accurately predict real world values. A prediction that better reflects the physical layout can be made be constructing a model of the chip in a 3D field solver, such as Ansoft's High Frequency Structure Simulator (HFSS).

The nominal value of the MOS capacitor, Cᵣ, needed to resonate the antenna at the center frequency can then be found in addition to the (now purely real) input impedance, Zᵢₙ, and the antenna efficiency, e_{cd}.

$$:= \frac{1}{ω} \cdot \frac{{X}_{in}}{{R}_{in}^{2} + {X}_{in}^{2}} {C}_{r} = 5.08153298 p$$

$${Z}_{in} := {R}_{in} + \frac{{X}_{in}^{2}}{{R}_{in}} {Z}_{in} = 321.83$$

$${e}_{c d} := \frac{{R}_{r}}{{R}_{r} + {R}_{L}} {e}_{c d} = 7.488 \times {10}^{- 5} \% \\ - 10 \cdot log ( {e}_{c d} ) = 61.256 Loss in dB .$$

The efficiency of the small loop antenna is low at the ISM center frequency of 915 MHz. The table below shows that the efficiency improves greatly as higher ISM bands are used. In contrast to this effect, there will be more attenuation at higher frequencies due to propagation through tissue. The ISM band center frequency that optimizes the link margin can be determined by developing a model of attenuation due to the presence of tissue as a function of frequency. This attenuation can then be compared to antenna efficiency so that the link margin can be optimized with respect to frequency.

TABLE 2
Single Square Loop Antenna Efficiency
at ISM Band Center Frequencies.

| | |
|---|---|
| ISM Band Center Frequency | Antenna Efficiency (dB) |

| | | |
|---|---|---|
| 6.780 | MHz | −135.8 |
| 13.560 | MHz | −125.3 |
| 27.120 | MHz | −114.7 |
| 40.68 | MHz | −108.6 |
| 915 | MHz | −61 |
| 2.450 | GHz | −46.3 |
| 5.800 | GHz | −33.2 |
| 24.125 | GHz | −11.8 |
| 61.25 | GHz | −1.9 |
| 122.5 | GHz | −0.2 |
| 245 | GHz | −0.0 |

The target process has 6 metallization layers available. This is typical of most manufacturing processes. If necessary this can be used as an advantage in the design of the loop antenna. One possibility is to print the loop on many layers and short the layers together with multiple vias so that many loops in parallel act as a single loop. This would have the effect of greatly lowering the loss resistance, designated R_{L} in the equations above. Lowering the loss resistance greatly improves antenna efficiency.

Another method of exploiting multiple metallization layers with respect to antenna design is to arrange the vias so that each loop acts as an independent coil of multiple turn loop antenna. Increasing the number of turns, N, increases the radiation resistance, Rᵣ, by a factor of N². This dramatic increase in radiation resistance equally affects antenna efficiency.

### MOS Capacitor as an Antenna Resonator

The last section presented a design process that resonated a small square loop antenna with a nominal value of a capacitor. The exact value of the capacitor is a function of ionizing radiation dose, thus the exact resonant frequency of the antenna is also a function of the same. The source is swept over a very narrow band, and the magnitude of the reflection from the capacitor-antenna pair is examined. The exact resonant frequency is determined, the value of the capacitor determined, and thus also the dose of ionizing radiation.

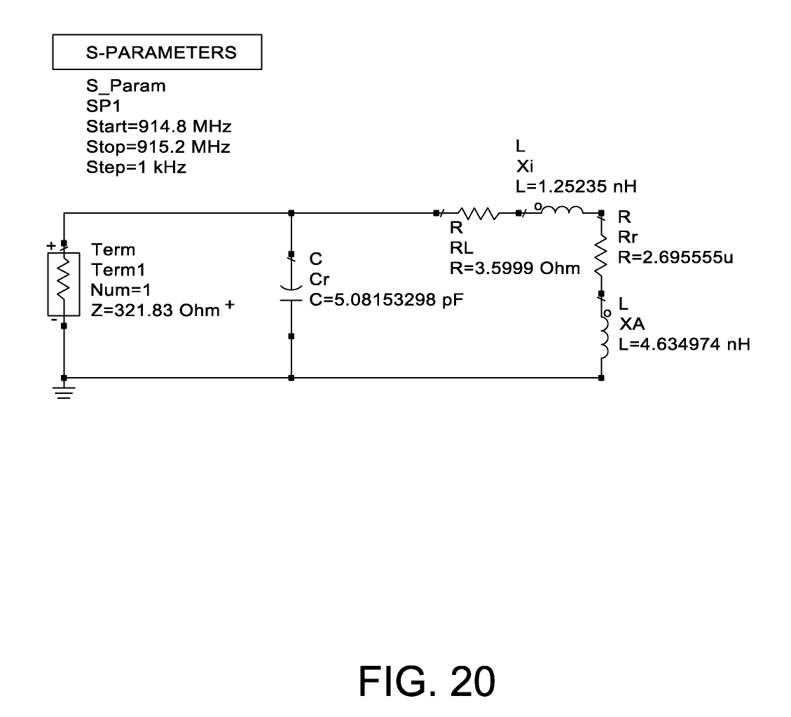

The equivalent circuit of the above calculations was modeled in the microwave simulation package, Agilent Advanced Design System (ADS). The simulation used the ISM band center frequency of 915 MHz and a sweep of only 400 kHz. The magnitude of the reflection coefficient, s₁₁, as a function of frequency was examined. The circuit is shown in FIG. 20.

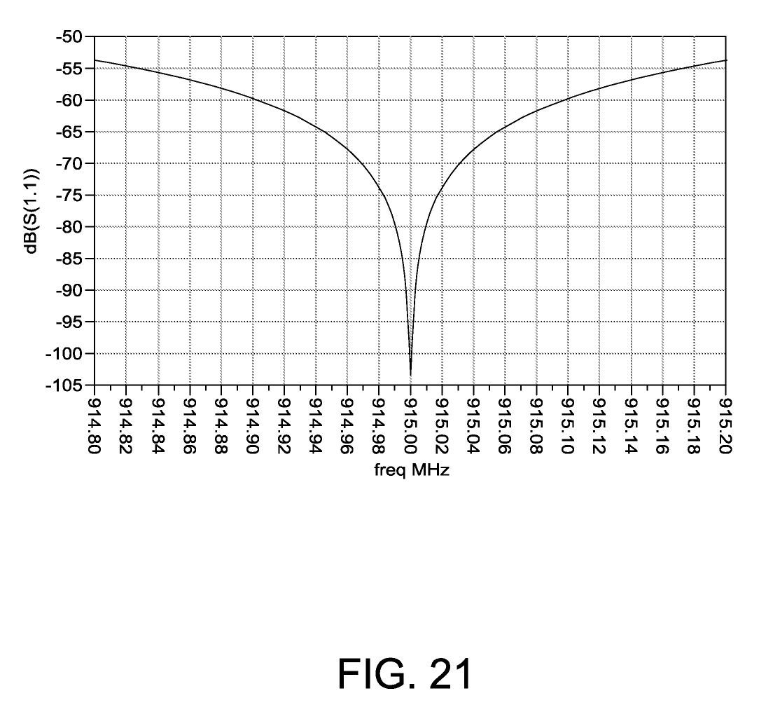

The simulation clearly shows that the magnitude of the reflection coefficient can be used to determine the circuit's resonant frequency. The plot of the reflection coefficient, s₁₁, is shown in FIG. 21.

### MOS Capacitor as a Frequency Multiplier

As stated in the introduction, as the source sweeps over the band, the implanted chip receives the energy and reflects it back out of the loop antenna. A MOS capacitor is a nonlinear device, and as such, it will reflect energy not only at the frequency of the source, but also at harmonics of the source. This is similar in effect to a common mixer, but the signal is self mixing. To avoid jamming the receiver with the source, it can receive the second harmonic of the center frequency.

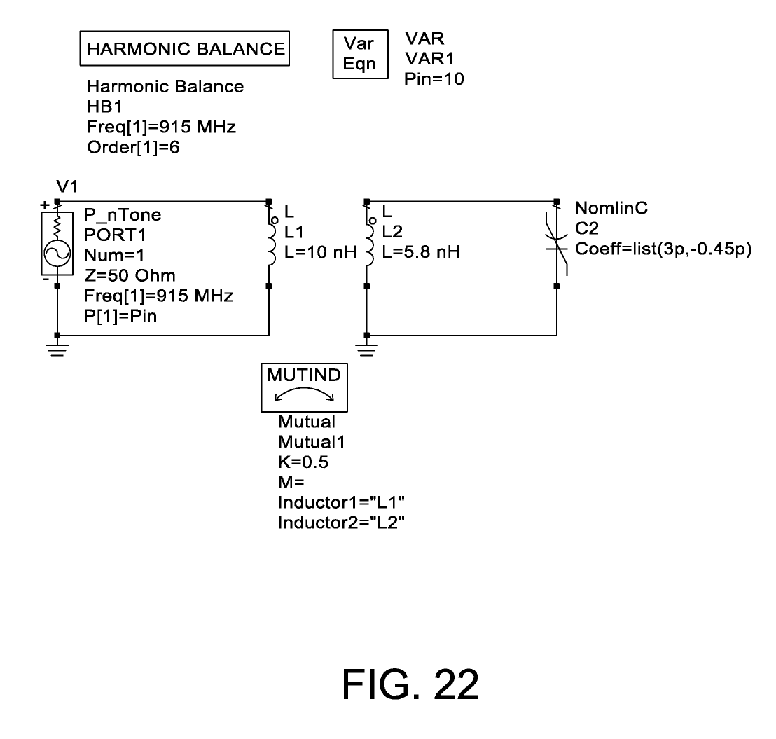

To show the validity of this approach, the circuit was simulated in Agilent ADS using a Harmonic Balance simulation with the same source frequency as the 915 MHz example. The antennas and transmission path were modeled as magnetically coupled inductors of the same value as the loop inductance. The MOS capacitor device itself was modeled using the nonlinear capacitor model available in the ADS library. A first-order equation was used to describe the device's voltage dependence. The zero bias nominal capacitance used was 3 pF, and the slope of the first order voltage dependence was −0.45 pF/V. These real world values were taken from experimental data measured from a previously fabricated MOS capacitor, and reflect the locally linear region in which the device is operating. The circuit is pictured in FIG. 22.

The Harmonic Balance simulation shows, as described by the results in FIG. 23, the fundamental frequency and the next 5 harmonics. It shows that the second order harmonic is not only present, but it is at a level of −30 dBc. Note that this circuit has not been optimized in any way, nor had the previously fabricated MOS capacitor design been optimized to work in this capacity. The simulation predicts a level of frequency conversion that should make signal reception at the receiver possible.

### Integrated ULP Micro-Dosimeter Chip

A crucial consideration for the proposed application with respect to its use in permanent seed brachytherapy is how each implanted device will be identified and ultimately be used for dose and position determination. As discussed in the transmitter design section, the change in RADCAP total capacitance will be determined by performing high resolution frequency scans within a narrow band. This band will be centered around a target frequency that uniquely matches the resonant frequency range for a particular device. The width of the band must be large enough to identify the radiation-shifted resonant frequencies in the first harmonic of the target device's input signal. Thus, for example, say one device may be configured with a RADCAP which will resonate at 1 Ghz and its harmonics prior to irradiation. If it is assumed that the RADCAP may be configured to shift 10% after a full range of 80 gray exposure and this shifts the resonance frequency by 2% or 20 Mhz in the first harmonic (more then enough to detect with a network analyzer), the narrow band range must be large enough to scan from 1.98 Ghz to 2.02 Ghz in the first harmonic band. Selecting a scan range to cover 1.95 Ghz to 2.05 Ghz will therefore be more than adequate as long as the Q of the resonator is high. A second device with a RFID frequency unique “far” from 1 Ghz can be designed simply by either changing the area of the RADCAP or dimensions of passives in the tuning circuitry. If the second device is tuned to resonate at 1.2 Ghz, then the scan range would need to cover 2.35 Ghz and 2.45 Ghz in the first harmonic, giving it good frequency separation from the first device. This simple and realizable example would allow for two more devices to be implanted, thereby enabling dose and location (via triangulation methods) measurements to be made.

All of the methods disclosed and claimed herein can be made and executed without undue experimentation in light of the present disclosure. While the apparatus and methods of this invention have been described in terms of preferred embodiments, it will be apparent to those of skill in the art that variations may be applied to the methods and in the steps or in the sequence of steps of the method described herein without departing from the concept, spirit and scope of the invention. In addition, modifications may be made to the disclosed apparatus and components may be eliminated or substituted for the components described herein where the same or similar results would be achieved. All such similar substitutes and modifications apparent to those skilled in the art are deemed to be within the spirit, scope, and concept of the invention as defined by the appended claims.

### REFERENCES

[1] G. C. Messenger and M. S. Ash, The Effects of Radiation on Electronic Systems. New York: Van Nostrand Reinhold, 1986.
[2] A. Holmes-Siedle, Radiat. Phys. Chem., vol. 28, pp. 235-244, 1986.
[3] F. B. McLean and T. R. Oldham, “Basic mechanisms of radiation effects in electronic materials and devices,” Harry Diamond Laboratories Technical Report, vol. HDL-TR, pp. 2129, 1987.
[4] T. R. Oldham, “Switching oxide traps,” in Radiation Effects and Soft Errors in Integrated Circuits and Electronic Devices, R. D. Schrimpf and D. M. Fleetwood, Eds. New Jersey: World Sci., 2004.
[5] G. P. Beyer, G. G. Mann, J. A. Pursley, E. T. Espenhahn, C. Fraisse, D. J. Godfrey, M. Oldham, T. B. Carrea, N. Bolick, and C. W. Scarantino, “An implantable MOSFET dosimeter for the measurement of radiation dose in tissue during cancer therapy,” IEEE Sensors Journal, vol. 8, 2008.
[6] X. J. Chen, H. J. Barnaby, R. D. Schrimpf, D. M. Fleetwood, R. L. Pease, and D. Platteter, “Nature of interface defect buildup in gated bipolar devices under low dose rate irradiation,” IEEE Trans Nucl. Sci., vol. 53, pp. 3649-3654, 2006.
[7] “Medical Implant Communications Service Frequency Table,” http://www.csgnetwork.com/micsfreqtable.html, May 25, 2008.
[8] “ISM bands,” http://en.wikipedia.org/wiki/ISM_band, May 25, 2008
[9] C.A. Balanis, Antenna Theory, Analysis and Design, 3^{rd} ed. Hoboken: John Wiley and Sons, Inc, 2005.

What is claimed is:

1. A radiation sensing capacitor comprising:
a silicon layer;
an insulator layer coupled to the silicon layer;
a silicon-insulator interface region coupling the silicon layer to the insulator layer; and
a plurality of hole-trapping precursors formed in the insulator layer proximate to the silicon-insulator interface region.

2. The radiation sensing capacitor of claim 1, the plurality of hole-trapping precursors comprising oxygen vacancies.

3. The radiation sensing capacitor of claim 1, the plurality of hole-trapping precursors comprising nano-cluster trapping sites.

4. The radiation sensing capacitor of claim 1, the insulator layer comprising silicon dioxide SiO₂.

5. The radiation sensing capacitor of claim 1, wherein the silicon layer comprises p-type doped silicon.

6. The radiation sensing capacitor of claim 1, further comprising:
a first conductor coupled to the silicon layer; and
a second conductor coupled to the insulator layer.

7. The radiation sensing capacitor of claim 6, wherein the first conductor and the second conductor comprise aluminum (Al).

8. A radiation sensor comprising:
a radiation sensing capacitor comprising:
a silicon layer;
an insulator layer coupled to the silicon layer;
a silicon-insulator interface region coupling the silicon layer to the insulator layer; and
a plurality of hole-trapping precursors formed in the insulator layer proximate to the silicon-insulator interface region; and
an antenna coupled to the radiation sensing capacitor.

9. The radiation sensor of claim 8, further comprising an isolation block, wherein the antenna is formed around the isolation block.

10. The radiation sensor of claim 8, the antenna comprising a patch antenna.

11. The radiation sensor of claim 8, the antenna comprising aluminum (Al).

12. The radiation sensor of claim 8, the antenna comprising a first contact portion and a second contact portion, wherein the first contact portion is coupled to the silicon layer and the second contact portion is coupled to the insulator layer.

13. The radiation sensor of claim 8, comprising a plurality of radiation sensing capacitors arranged such that each of the plurality of radiation sensing capacitors are selectably coupled to the antenna.

14. The radiation sensor of claim 8, configured to reflect a response signal having a primary frequency and a plurality of harmonic frequencies in response to interrogation from a remote radio-frequency source.

15. The radiation sensor of claim 14, wherein the primary frequency and the harmonic frequencies are determined by a level of radiation sensed by the radiation sensing capacitor.

16. A method of manufacturing a radiation sensor comprising:
forming a silicon layer;
forming an insulator layer coupled to the silicon layer such that a silicon-insulator interface region couples the silicon layer to the insulator layer; and
forming a plurality of hole-trapping precursors formed in the insulator layer proximate to the silicon-insulator interface region.

17. The method of claim 16, wherein forming a silicon layer comprises:
providing a silicon substrate having a sacrificial layer formed thereon;
etching the sacrificial layer to provide one or more groove windows;
etching one or more grooves into the substrate through the grove windows of the sacrificial layer;
removing the sacrificial layer;
forming a layer on a first surface of the silicon substrate and in the one or more grooves; and
reducing the thickness of the silicon substrate from a second surface opposite the first surface until at least a portion of the oxide layer formed in the one or more grooves is exposed through the second surface.

18. The method of claim 16, further comprising:
forming a polysilicon layer on the oxide layer; and
forming a metal layer over the polysilicon layer.

19. The method of claim 17, wherein forming the insulator layer comprises forming the insulator layer on the second surface.

20. The method of claim 16, further comprising:
forming a patterned polysilicon layer in the insulator layer; and
forming a metal contact with the polysilicon layer through the insulator layer.

21. The method of claim 16, further comprising coupling the silicon layer and the insulator layer to an antenna.
